(19) United States
(12) Patent Application Publication
(10) Pub. No.: US 2026/0282859 A1
(43) Pub. Date: Sep. 17, 2026

(54) FABRICATION METHOD COMBINING LASER DIRECT IMAGING (LDI) AND PHOTOMASK PROCESSING

(71) Applicant: Microchip Technology Inc., Chandler, AZ (US)

(72) Inventor: Julius Andrew Kovats, Manitou Springs, CO (US)

(73) Assignee: Microchip Technology Inc., Chandler, AZ (US)

(21) Appl. No.: 19/257,684

(22) Filed: Jul. 2, 2025

Related U.S. Application Data
(60) Provisional application No. 63/773,219, filed on Mar. 17, 2025.

(51) Int. Cl. H01L 21/768; G03F 7/00; H01L 25/00

(52) U.S. Cl. CPC H10W 20/068; G03F 7/70383; H10W 90/00

(57) ABSTRACT

A method of forming an IC package device is provided. A first IC device is arranged adjacent a second IC device on a substrate, the first IC device including first circuitry and a plurality of first pads and the second IC device including second circuitry and a plurality of second pads, wherein the second IC device is misaligned relative to a target position, such that the second pads are misaligned relative to target positions for the second pads. Laser direct imaging (LDI) processing is used to form (a) substitute second pads at positions corresponding with the target positions for the second pads and (b) second pad connections between the misaligned second pads and the substitute second pads, and a photomask imaging process is used to form IC device interconnections to connect the substitute second pads to first circuitry of the first IC device.

### RELATED APPLICATION

This application claims priority to commonly owned U.S. Provisional Patent Application No. 63/773,219 filed Mar. 17, 2025, the entire contents of which are hereby incorporated by reference for all purposes.

### TECHNICAL FIELD

The present disclosure relates to a fabrication method that combines laser direct imaging (LDI) with photomask processing, for example for connecting Heterogenous Integration (HI) chiplets.

### BACKGROUND

Laser direct imaging (LDI) is a photolithography process commonly used in panel-level processing (PLP) for integrated circuit (IC) devices, wherein a highly focused laser beam traces a digitally saved pattern on a resist, as opposed to the conventional photomask-based process in which light is passed through a photomask to expose a selected pattern on the resist. LDI has various advantages, including eliminating the need for a photomask, and typically providing increased process speed.

However, LDI typically cannot achieve the small line/space dimensions achieved by photomask imaging. For example, Gen 1 LDI and Gen 2 LDI are generally capable of about 7 um Line/Space (L/S) and about 2 um L/S, respectively, as compared to photomask imaging which can achieve sub-micron lines. In contrast, photomask imaging can achieve sub-micron lines and line spacing. The size limitations of LDI may be problematic for certain applications requiring smaller L/S. For example, heterogenous integration (HI) chiplets in which analog and digital blocks are formed separately and then connected to each other may require thousands of connections, while the L/S limitations of LDI processing may allow only hundreds of connections between chiplets, unless many layers of Redistribution (RDL) are used, which can become very expensive.

There is a need enable smaller line/space creation than achievable by LDI for certain applications, for example for connecting chiplets or other IC devices, for example to from Heterogenous Integration (HI) chiplets.

### SUMMARY

The present disclosure provides methods that combine Laser Direct Imaging (LDI) and traditional photomask imaging processes to connect chiplets or other IC devices while correcting for misalignments, which may achieve substantially finer line/spacing than using LDI alone, to thereby increasing the allowed number of chiplet interconnections from hundreds to thousands (or more), for example to thereby enable Heterogenous Integration of chiplets at a practical level using existing fabrication tools.

Some examples provide a method including connecting two IC devices (e.g., chiplets) using a combination of Laser Direct Imaging (LDI) and traditional photomask patterning. The chiplets may first be molded into a standard Panel Level Package (PLP) format, for example a 300 mm round panel. The two chiplets may be offset relative to each other due to pick-and-place inaccuracy, which are then magnified in the mold and cure steps and may be too far out of alignment for standard photomask imaging. However, the LDI process (e.g., using Adaptive Patterning techniques) can then be used to reposition (correct) the pad positions on one of the chiplets. The resulting re-positioned pads can then be connected to each other using photomask imaging at much finer geometries than possible with LDI, such that thousands (for example) of interconnection traces may be formed between two typical chiplets, as opposed to hundreds (for example) using LDI processing.

One aspect provides a method of forming an IC package device. A first IC device is arranged adjacent a second IC device on a substrate, the first IC device including first IC device circuitry and a plurality of first IC device pads and the second IC device including second IC device circuitry and a plurality of second IC device pads, wherein the second IC device is misaligned relative to a target position for the second IC device, such that respective positions of the second IC device pads are misaligned relative to target positions for respective second IC device pads. Laser direct imaging (LDI) processing is used to form (a) substitute second IC device pads at positions corresponding with the target positions for the second IC device pads and (b) second IC device pad connections between the misaligned second IC device pads and the substitute second IC device pads. Photomask imaging processing is then used to form IC device interconnections to connect the substitute second IC device pads to respective first IC device circuitry of the first IC device.

In some examples, the first IC device comprises a first chiplet and the second IC device comprises a second chiplet.

In some examples, the IC device interconnections formed by the photomask imaging processing connect the substitute second IC device pads to respective first IC device pads.

In some examples, the first IC device is misaligned relative to a target position for the first IC device, such that respective positions of the first IC device pads are misaligned relative to target positions for respective first IC device pads; the method comprises using LDI processing to form (a) substitute first IC device pads at positions corresponding with the target positions for the first IC device pads and (b) first IC device pad connections between the misaligned first IC device pads and the substitute first IC device pads; and the IC device interconnections formed by the photomask imaging processing connect the substitute second IC device pads to respective substitute first IC device pads.

In some examples, the first IC device comprises a digital block and the second IC device comprises an analog block, or the first IC device comprises an analog block and the second IC device comprises a digital block.

In some examples, at least one of the IC device interconnections formed by the photomask imaging process has a smaller line/space dimension than a minimum line/space capability of the LDI process.

In some examples, the second IC device being misaligned relative to a target position for the second IC device comprises at least one of (a) the second IC device laterally misaligned in at least one direction from a target lateral position or (b) the second IC device rotationally misaligned from a target rotational position.

In some examples, arranging the first IC device adjacent the second IC device comprises using a pick-and-place tool to arrange the first IC device and the second IC device on the substrate.

In some examples, the method includes forming a plurality of package pads outside respective footprints of the first IC device and second IC device, and forming connections between respective package pads and respective ones of the first IC device pads and/or respective ones of the substitute second IC device pads.

In some examples, performing the LDI process comprises using adaptive patterning to form the substitute second IC device pads and the second IC device pad connections.

Another aspect provides a method of forming an IC package device. A device layout is provided for a pads for a heterogenous integration IC device including multiple IC devices including at least a first IC device including a plurality of first IC device pads and a second IC device including a plurality of second IC device pads, the device layout specifying (a) a target position for the first IC device, including target positions for respective first IC device pads and (b) a target position for the second IC device, including target positions for respective second IC device pads. The first IC device and the second IC device are arranged on a substrate, wherein the second IC device is misaligned relative to the target position for the second IC device such that respective positions of the second IC device pads are misaligned relative to the target positions for respective second IC device pads. An LDI process is performed to form (a) substitute second IC device pads on the second IC device at positions corresponding with the target positions for the second IC device pads, and (b) substitute pad connections connecting respective substitute second IC device pads to respective misaligned second IC device pads. A photomask imaging process is performed to form IC device interconnections to connect respective first IC device pads to respective substitute second IC device pads.

In some examples, the first IC device comprises a first chiplet and the second IC device comprises a second chiplet.

In some examples, the first IC device comprises a digital block and the second IC device comprises an analog block.

In some examples, at least one of the IC device interconnections formed by the photomask imaging process has a smaller line/space dimension than a minimum line/space capability of the LDI process.

In some examples, the first IC device being misaligned relative to the target position for the first IC device comprises the first IC device misaligned laterally and/or rotationally relative to the target position for the first IC device.

In some examples, the method includes forming a plurality of package pads outside respective footprints of the first IC device and second IC device, and forming connections between respective package pads and respective ones of the first IC device pads and/or substitute second IC device pads.

Another aspect provides another method of forming an IC package device. A first IC device is arranged on a substrate, the first IC device including first IC device circuitry, a plurality of first IC device pads, and a plurality of first conductive pillars extending upwardly from the plurality of first IC device pads. A second IC device is arranged on the first IC device in a stacked arrangement, the second IC device including second IC device circuitry, a plurality of second IC device pads, and a plurality of second conductive pillars extending upwardly from the plurality of second IC device pads. The second IC device is misaligned relative to a target position for the second IC device, such that respective positions of the second conductive pillars are misaligned relative to target positions for respective second conductive pillars. LDI processing is used to form (a) substitute pads at positions corresponding with the target positions for the second conductive pillars and (b) second pad connections between the misaligned second conductive pillars and the substitute pads, and photomask imaging is used processing to form IC device interconnections to connect the substitute pads to respective first conductive pillars of the first IC device.

In some examples, the first IC device comprises a first chiplet and the second IC device comprises a second chiplet.

In some examples, the first IC device comprises a digital block and the second IC device comprises an analog block, or the first IC device comprises an analog block and the second IC device comprises a digital block.

In some examples, at least one of the IC device interconnections formed by the photomask imaging process has a smaller line/space dimension than a minimum line/space capability of the LDI process.

### BRIEF DESCRIPTION OF THE DRAWINGS

Example aspects of the present disclosure are described below in conjunction with the figures, in which:

FIGS. 1-3 are top-down views showing an example method of forming an IC package device including multiple IC devices (e.g., chiplets) arranged side-by-side, wherein the method includes both laser direct imaging (LDI) and photomask processing to correct a misalignment between the IC devices and connect the IC devices to each other; and

FIGS. 4-7 are top-down views showing an example method of forming an IC package device including multiple IC devices (e.g., chiplets) arranged in a stacked manner, wherein the method includes both laser direct imaging (LDI) and photomask processing to correct a misalignment between the IC devices and connect the IC devices to each other.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

FIGS. 1-3 are top-down views showing an example method of forming an IC package device, for example a multiple-chiplet device, which method includes both laser direct imaging (LDI) and photomask processing to connect misaligned IC devices.

As shown in FIG. 1, a first IC device 100 is arranged adjacent a second IC device 102 on a substrate 104. In some examples, the first IC device 100 and second IC device 102 comprise first and second chiplets. In some examples, the first IC device 100 is an analog chiplet and the second IC device 102 is a digital chiplet, or vice versa. In other examples, both the first IC device 100 and second IC device 102 comprise analog chiplets, or both comprise digital chiplets. The first IC device 100 includes first IC device circuitry 110 connected to a plurality of first IC device pads 112, and the second IC device 102 includes second IC device circuitry 114 connected to a plurality of second IC device pads 116. The substrate 104 may comprise any supporting structure on which the first IC device 100 and second IC device 102 may be mounted or otherwise arranged. In some examples, substrate 104 may comprise an adhesive tape or other temporary carrier that may be subsequently removed from the IC package device being formed, e.g., after connecting the first IC device 100 and second IC device 102 as discussed below. In other examples, substrate 104 may form a permanent component of the formed IC package device.

A device layout may be provided for the IC package device being formed. The device layout may specify (a) a target position for the first IC device 100, including target positions for respective first IC device pads 112 and (b) a target position for the second IC device 102, including target positions for respective second IC device pads 116. In the illustrated example, the second IC device 102 is misaligned relative to the target position (indicated at TP₁₀₂) specified in the device layout for the second IC device 102 (and thus misaligned relative to the first IC device 100), such that respective positions of the second IC device pads 116 are misaligned relative to target positions (indicated at TP₁₁₆) for respective second IC device pads 116. The second IC device 102 may be misaligned relative to the target position TP₁₀₂ laterally (e.g., in the x-direction and/or y-direction) and/or rotationally (e.g., about the z-axis). Such misalignment may result from various process inaccuracies. For example, in an implementation in which a pick-and-place tool is used to arrange the first IC device 100 and second IC device 102 on the substrate 104, the pick-and-place tool may inaccurately position the second IC device 102 relative to the target position TP₁₀₂.

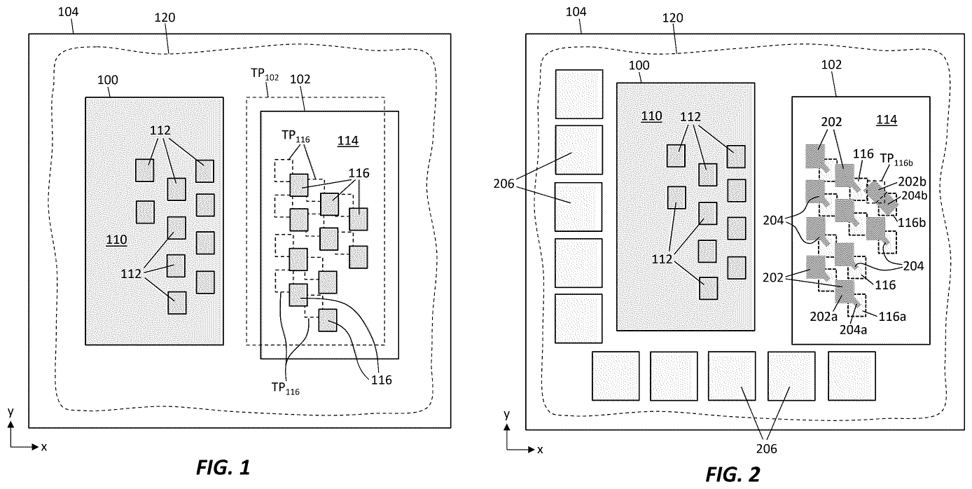

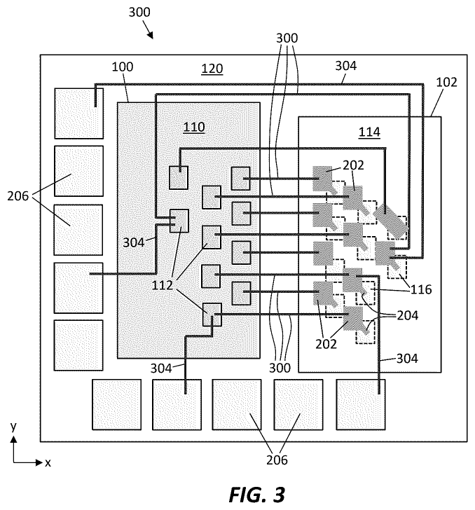

In some examples, the first IC device 100 is also misaligned relative to a target position for the first IC device 100. For example, a pick-and-place tool may inaccurately position both the first IC device 100 and second IC device 102 relative to respective target positions. In such examples, either the first IC device 100 or the second IC device 102 (e.g., the larger of the two devices) is selected as the reference device, and LDI processing and photomask imaging discussed below with reference to FIGS. 2 and 3 may be calibrated (aligned) to the selected reference device, such that the disclosed process may be similarly performed with one misaligned device (IC device 100 or 102) or both misaligned devices (IC devices 100 and 102).

As shown in FIG. 1, in some examples a mold compound 120 (e.g., an epoxy or other polymer) may be applied or formed over the first IC device 100 and second IC device 102, cured, and ground down or otherwise planarized to expose the first IC device pads 112 and second IC device pads 116.

As shown in FIG. 2, laser direct imaging (LDI) processing (for example including Adaptive Patterning techniques) is performed to form (a) a plurality of substitute second IC device pads 202 at positions corresponding with the target positions TP₁₁₆ (shown in FIG. 1) for respective second IC device pads 116 and (b) a plurality of second IC device pad connections 204 connecting the misaligned second IC device pads 116 with respective substitute second IC device pads 202. In this manner, LDI processing may thus be used to reposition (correct) the pad positions of the second IC device 102. In some examples, the second IC device pad connections 204 and/or the second IC device pads 202 may be formed in at least one redistribution layer (RDL) formed over the second IC device pads 116.

In some examples or instances, respective substitute second IC device pads 202 may be formed with sizes generally similar to corresponding second IC device pads 116, while respective second IC device pad connections 204 may be formed as elongated traces or lines, e.g., with smaller widths than the substitute second IC device pads 202. For example, the example substitute second IC device pad 202a shown in FIG. 2 is formed as a pad having a similar size as the associated second IC device pad 116a, while the example second IC device pad connections 204a is formed as a narrow trace connecting the substitute second IC device pad 202a with the corresponding second IC device pad 116.

In other examples or instances, respective substitute second IC device pads 202 and associated second IC device pad connections 204 may be formed as contiguous shapes, e.g., having a uniform width or other dimensions. For example, the example substitute second IC device pad 202b and example second IC device pad connections 204b shown in FIG. 2 are formed as a rectangular element, wherein (a) the second IC device pad connections 204b comprises a portion of the rectangular element formed over and connected to the associated second IC device pad 116b defines the second IC device pad connection 204b, and (b) the substitute second IC device pad 202b comprises another portion of the rectangular element having a location corresponding with the original target position TP_{116b} of the associated second IC device pad 116b.

In addition, in some examples a plurality of package pads 206 are formed outside respective footprints of the first IC device 100 and second IC device 102 using LDI processing, either concurrently with, or before or after, the formation of substitute second IC device pads 202 and second IC device pad connections 204. In other examples, package pads 206 may be formed by photomask imaging, e.g., concurrently with the formation of IC device interconnections 300 and/or package pad interconnections 304 discussed below reference to FIG. 3. In some examples, package pads 206 may comprise land grid array (LGA) pads, ball grid array (BGA) pads, or quad flat no-leads (QFN) pads, depending on the type of IC package device being formed.

As shown in FIG. 3, photomask imaging processing may be performed to form (a) a plurality of IC device interconnections 300 to connect respective substitute second IC device pads 202 to respective first IC device pads 112, to thereby define electrical connections between second IC device circuitry 114 of the second IC device 102 and first IC device circuitry 110 of the first IC device 100, and operationally (b) a plurality of package pad interconnections 304 to connect respective package pads 206 with respective first IC device pads 112 and/or substitute second IC device pads 202. In some examples, the IC device interconnections 300 and package pad interconnections 304 may comprise conductive traces formed in RDL or other metal layer.

In some examples, respective IC device interconnections 300 and/or package pad interconnections 304 formed by photomask imaging processing may respectively have a smaller line/space dimension than the substitute second IC device pads 202 and second IC device pad connections 204 formed by LDI processing (discussed above with reference to FIG. 2). Moreover, in some examples, respective IC device interconnections 300 and package pad interconnections 304 formed by photomask imaging processing have smaller line/space dimensions than a minimum line/space capability of the LDI processing used to form the substitute second IC device pads 202 and second IC device pad connections 204. For example, the LDI processing used to form the substitute second IC device pads 202 and second IC device pad connections 204 may have a minimum line/space capability of about 7 μm (e.g., typical of Gen 1 LDI) or about 2 μm (e.g., typical of Gen 2 LDI), whereas respective IC device interconnections 300 and/or package pad interconnections 304 may have a line width and/or spacing of less than 2 μm or less than 1 μm (sub-micron).

The smaller line/space dimensions of IC device interconnections 300 and/or package pad interconnections 304 provided by the use of photomask imaging (as opposed to LDI processing) may allow more connections between the first IC device 100 and second IC device 102 and from the first and/or second IC devices 100, 102 to respective package pads 206. For example, in examples in which the first and second IC devices 100 and 102 comprises typical chiplets, the use of photomask imaging to form IC device interconnections 300 and/or package pad interconnections 304 may allow thousands of chiplet-chiplet connections between the chiplets, as compared to LDI processing that may allow only hundreds of chiplet-chiplet connections.

In some examples, additional plating may be applied to respective package pads 206 to improve the wire bond characteristics of the package pads 206. In some examples, the substrate 104 may then be removed (e.g., an adhesive tape substrate may be peeled off) and the remaining structure (e.g., panel) may be diced to define an IC package device 300 shown in FIG. 3, including the first IC device 100 and second IC device 102 connected to each other and to package pads 206, and physically supported by the mold compound 120. In some examples, the IC package device 300 may define a discrete IC package. In other examples, the IC package device 300 may be further processed, packaged, or combined with other components to form an IC package.

In this manner, the method of forming the example IC package device 300 may combine advantageous aspects of LDI (for example eliminating the need for photomasks, and typically providing increased process speed) with photomask imaging (fineline geometries), to connect the first IC device 100 and second IC device 102 while corrected for the device misalignment as discussed above.

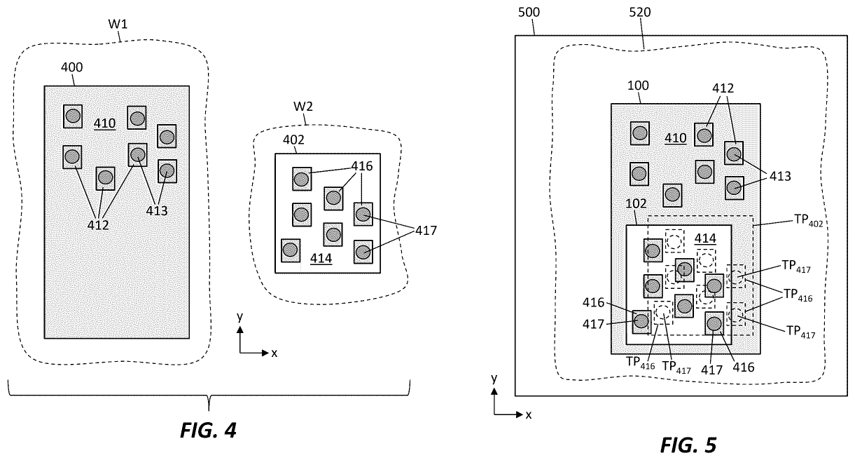

FIGS. 4-7 are top-down views showing another example method of forming an IC package device, for example a multiple-chiplet device, including both LDI and photomask processing to connect misaligned IC devices. Unlike the example method shown in FIGS. 1-3 in which a pair of IC devices 100 and 102 (e.g., a pair of chiplets) are arranged side-by-side on a carrier 104, the example method shown in FIGS. 4-7 involves arranging a pair of IC devices (e.g., chiplets) arranged in a stacked arrangement.

As shown in FIG. 4, a first IC device 400 may be formed on a first wafer W1 and a second IC device 402 may be formed on a second wafer W2. In some examples, the first IC device 400 and second IC device 402 comprise first and second chiplets, for example two analog chiplets, two digital chiplets, or one analog chiplet and one digital chiplet.

The first IC device 400 may be formed with first IC device circuitry 410 connected to a plurality of first IC device pads 412, and first conductive pillars 413 extending upwardly (in the z-direction out of the page) from respective first IC device pads 412. Similarly, the second IC device 402 may be formed with second IC device circuitry 414 connected to a plurality of second IC device pads 416, and second conductive pillars 417 extending upwardly (in the z-direction out of the page) from respective second IC device pads 416.

As show in FIG. 5, the first IC device 400 is arranged on a substrate 500, and the second IC device 402 is mounted on the first IC device 400, e.g., in an area free of first IC device pads 412. The second IC device 402 may be arranged within the footprint of the first IC device 400, or may partially overlap the first IC device 400 in at least one lateral direction. Top surfaces of first conductive pillars 413 extending upwardly from first IC device pads 412 may be co-planar or substantially co-planar with second conductive pillars 417 extending upwardly from second IC device pads 416

The substrate 500 may comprise any supporting structure on which the first IC device 400 and second IC device 402 may be mounted or otherwise arranged. Substrate 500 may comprise an adhesive tape or other temporary carrier that may be subsequently removed, or alternatively may form a permanent component of the formed IC package device, e.g., as discussed above regarding substrate 104.

A mold compound 520 (e.g., an epoxy or other polymer) may be applied or formed over the first IC device 400 and second IC device 402, cured, and ground down or otherwise planarized to expose the top surfaces of first conductive pillars 413 and second conductive pillars 417.

A device layout may be provided for the IC package device being formed. The device layout may specify (a) a target position for the first IC device 400, including target positions for respective first conductive pillars 413 and (b) a target position for the second IC device 402, including target positions for respective second conductive pillars 417. As shown in FIG. 5, the second IC device 402 may be misaligned (laterally and/or rotationally) relative to the target position (indicated at TP₄₀₂) specified in the device layout for the second IC device 402 (and thus misaligned relative to the first IC device 400), such that respective positions of the second conductive pillars 417 are misaligned relative to target positions (indicated at TP₁₁₇) for respective second conductive pillars 417.

As shown in FIG. 6, LDI processing (for example including Adaptive Patterning techniques) is performed to form (a) a plurality of substitute pads 602 at positions corresponding with the target positions TP₁₁₇ (shown in FIG. 5) for respective second conductive pillars 417 and (b) a plurality of substitute pad connections 604 connecting the misaligned second conductive pillars 417 with respective substitute pads 602. In this manner, LDI processing may thus be used to reposition (correct) the positions of the second conductive pillars 417. In some examples, the substitute pads 602 and/or substitute pad connections 604 may be formed in at least one redistribution layer (RDL).

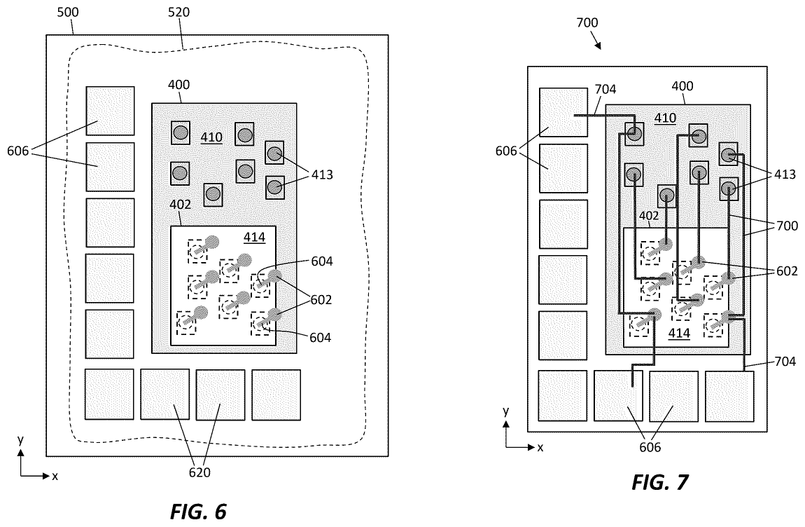

In addition, in some examples a plurality of package pads 606 are formed outside respective footprints of the first IC device 100 using LDI processing, either concurrently with, or before or after, the formation of substitute pads 602 and substitute pad connections 604. In other examples, package pads 606 may be formed by photomask imaging, e.g., concurrently with the formation of IC device interconnections 700 and/or package pad interconnections 704 discussed below reference to FIG. 7. In some examples, package pads 606 may comprise land grid array (LGA) pads, ball grid array (BGA) pads, or quad flat no-leads (QFN) pads, depending on the type of IC package device being formed.

As shown in FIG. 7, photomask imaging processing may be performed to form (a) a plurality of IC device interconnections 700 to connect respective substitute pads 602 to respective first conductive pillars 413, to thereby define electrical connections between second IC device circuitry 414 of the second IC device 402 and first IC device circuitry 410 of the first IC device 400, and operationally (b) a plurality of package pad interconnections 704 to connect respective package pads 606 with respective first conductive pillars 413 and/or substitute pads 602. In some examples, the IC device interconnections 700 and package pad interconnections 704 may comprise conductive traces formed in RDL or other metal layer.

In some examples, respective IC device interconnections 700 and/or package pad interconnections 704 formed by photomask imaging processing may respectively have a smaller line/space dimension than the substitute pads 602 and substitute pad connections 604 formed by LDI processing (discussed above with reference to FIG. 6). Moreover, in some examples, respective IC device interconnections 700 and package pad interconnections 704 formed by photomask imaging processing have smaller line/space dimensions than a minimum line/space capability of the LDI processing used to form the substitute pads 602 and substitute pad connections 604. For example, the LDI processing used to form the substitute pads 602 and substitute pad connections 604 may have a minimum line/space capability of about 7 μm (e.g., typical of Gen 1 LDI) or about 2 μm (e.g., typical of Gen 2 LDI), whereas respective IC device interconnections 700 and/or package pad interconnections 704 may have a line width and/or spacing of less than 2 μm or less than 1 μm (sub-micron).

As discussed above, the smaller line/space dimensions of IC device interconnections 700 and/or package pad interconnections 704 provided by the use of photomask imaging (as opposed to LDI processing) may allow more connections between the first IC device 400 and second IC device 402 and from the first and/or second IC devices 400, 402 to respective package pads 606. For example, in examples in which the first and second IC devices 400 and 402 comprises typical chiplets, the use of photomask imaging to form IC device interconnections 700 and/or package pad interconnections 704 may allow thousands of chiplet-chiplet connections between the chiplets, as compared to LDI processing that may allow only hundreds of chiplet-chiplet connections.

In some examples, additional plating may be applied to respective package pads 606 to improve the wire bond characteristics of the package pads 606. In some examples, the substrate 500 may then be removed (e.g., an adhesive tape substrate 500 may be peeled off) and the remaining structure (e.g., panel) may be diced to define an IC package device 700 shown in FIG. 7, including the first IC device 400 and second IC device 402 connected to each other and to package pads 606, and physically supported by the mold compound 520. In some examples, the IC package device 700 may define a discrete IC package. In other examples, the IC package device 700 may be further processed, packaged, or combined with other components to form an IC package.

Although example embodiments have been described above, other variations and embodiments may be made from this disclosure without departing from the spirit and scope of these embodiments.

1. A method, comprising:
arranging a first IC device adjacent a second IC device on a substrate, the first IC device including first IC device circuitry and a plurality of first IC device pads and the second IC device including second IC device circuitry and a plurality of second IC device pads, wherein the second IC device is misaligned relative to a target position for the second IC device, such that respective positions of the second IC device pads are misaligned relative to target positions for respective second IC device pads;
using laser direct imaging (LDI) processing to form (a) substitute second IC device pads at positions corresponding with the target positions for the second IC device pads and (b) second IC device pad connections between the misaligned second IC device pads and the substitute second IC device pads; and
using photomask imaging processing to form IC device interconnections to connect the substitute second IC device pads to respective first IC device circuitry of the first IC device.

2. The method of claim 1, wherein the first IC device comprises a first chiplet and the second IC device comprises a second chiplet.

3. The method of claim 1, wherein the IC device interconnections formed by the photomask imaging processing connect the substitute second IC device pads to respective first IC device pads.

4. The method of claim 1, wherein:
the first IC device is misaligned relative to a target position for the first IC device, such that respective positions of the first IC device pads are misaligned relative to target positions for respective first IC device pads;
the method comprises using LDI processing to form (a) substitute first IC device pads at positions corresponding with the target positions for the first IC device pads and (b) first IC device pad connections between the misaligned first IC device pads and the substitute first IC device pads; and
the IC device interconnections formed by the photomask imaging processing connect the substitute second IC device pads to respective substitute first IC device pads.

5. The method of claim 1, wherein the first IC device comprises a digital block and the second IC device comprises an analog block, or the first IC device comprises an analog block and the second IC device comprises a digital block.

6. The method of claim 1, wherein at least one of the IC device interconnections formed by the photomask imaging process has a smaller line/space dimension than a minimum line/space capability of the LDI process.

7. The method of claim 1, wherein the second IC device being misaligned relative to a target position for the second IC device comprises at least one of (a) the second IC device laterally misaligned in at least one direction from a target lateral position or (b) the second IC device rotationally misaligned from a target rotational position.

8. The method of claim 1, wherein arranging the first IC device adjacent the second IC device comprises using a pick-and-place tool to arrange the first IC device and the second IC device on the substrate.

9. The method of claim 1, comprising forming a plurality of package pads outside respective footprints of the first IC device and second IC device, and forming connections between respective package pads and respective ones of the first IC device pads and/or respective ones of the substitute second IC device pads.

10. The method of claim 1, wherein performing the LDI process comprises using adaptive patterning to form the substitute second IC device pads and the second IC device pad connections.

11. A method, comprising:
providing a device layout for a heterogenous integration IC device including multiple IC devices including at least a first IC device including a plurality of first IC device pads and a second IC device including a plurality of second IC device pads, the device layout specifying (a) a target position for the first IC device, including target positions for respective first IC device pads and (b) a target position for the second IC device, including target positions for respective second IC device pads;
arranging the first IC device and the second IC device on a substrate, wherein the second IC device is misaligned relative to the target position for the second IC device such that respective positions of the second IC device pads are misaligned relative to the target positions for respective second IC device pads;
performing a laser direct imaging (LDI) process to form (a) substitute second IC device pads on the second IC device at positions corresponding with the target positions for the second IC device pads, and (b) substitute pad connections connecting respective substitute second IC device pads to respective misaligned second IC device pads; and
performing a photomask imaging process to form IC device interconnections to connect respective first IC device pads to respective substitute second IC device pads.

12. The method of claim 11, wherein the first IC device comprises a first chiplet and the second IC device comprises a second chiplet.

13. The method of claim 11, wherein the first IC device comprises a digital block and the second IC device comprises an analog block.

14. The method of claim 11, wherein at least one of the IC device interconnections formed by the photomask imaging process has a smaller line/space dimension than a minimum line/space capability of the LDI process.

15. The method of claim 11, wherein the second IC device being misaligned relative to the target position for the second IC device comprises the second IC device misaligned laterally and/or rotationally relative to the target position for the second IC device.

16. The method of claim 11, comprising forming a plurality of package pads outside respective footprints of the first IC device and second IC device, and forming connections between respective package pads and respective ones of the first IC device pads and/or substitute second IC device pads.

17. A method, comprising:
arranging a first IC device on a substrate, the first IC device including first IC device circuitry, a plurality of first IC device pads, and a plurality of first conductive pillars extending upwardly from the plurality of first IC device pads,
arranging a second IC device on the first IC device in a stacked arrangement, the second IC device including second IC device circuitry, a plurality of second IC device pads, and a plurality of second conductive pillars extending upwardly from the plurality of second IC device pads;
wherein the second IC device is misaligned relative to a target position for the second IC device, such that respective positions of the second conductive pillars are misaligned relative to target positions for respective second conductive pillars;
using laser direct imaging (LDI) processing to form (a) substitute pads at positions corresponding with the target positions for the second conductive pillars and (b) second pad connections between the misaligned second conductive pillars and the substitute pads; and
using photomask imaging processing to form IC device interconnections to connect the substitute pads to respective first conductive pillars of the first IC device.

18. The method of claim 17, wherein the first IC device comprises a first chiplet and the second IC device comprises a second chiplet.

19. The device of claim 17, wherein the first IC device comprises a digital block and the second IC device comprises an analog block, or the first IC device comprises an analog block and the second IC device comprises a digital block.

20. The device of claim 17, wherein at least one of the IC device interconnections formed by the photomask imaging process has a smaller line/space dimension than a minimum line/space capability of the LDI process.
